(19) United States
(12) Patent Application Publication
(10) Pub. No.: US 2009/0206371 A1
(43) Pub. Date: Aug. 20, 2009

(54) NITRIDE SEMICONDUCTOR DEVICE AND POWER CONVERSION APPARATUS INCLUDING THE SAME

(76) Inventor: Tohru OKA, Kitakatsuragi-gun (JP)

Correspondence Address: BIRCH STEWART KOLASCH & BIRCH, PO BOX 747, FALLS CHURCH, VA, 22040-0747, US

(21) Appl. No.: 12/388,270

(22) Filed: Feb. 18, 2009

(30) Foreign Application Priority Data
Feb. 19, 2008 (JP) 2008-037298

(51) Int. Cl. H01L 29/205

(52) U.S. Cl. 257/201; 257/E29.091

(57) ABSTRACT

A nitride semiconductor device includes a first, a second, and a third nitride semiconductor layers that are laminated on a foundation semiconductor layer in stated order, the third nitride semiconductor layer having a wider band gap as compared with the second nitride semiconductor layer, a recess area that is dug from an upper surface of the third nitride semiconductor layer down to a middle of the second nitride semiconductor layer, a first electrode and a second electrode respectively formed on one side and the other side of the recess area so as to be in contact with one of the third nitride semiconductor layer and the second nitride semiconductor layer, a dielectric film formed on the third nitride semiconductor layer and an inner surface of the recess area, and a control electrode formed on the dielectric film in the recess area.

This nonprovisional application is based on Japanese Patent Application No. 2008-037298 filed on Feb. 19, 2008, with the Japan Patent Office, the entire contents of which are hereby incorporated by reference.

### BACKGROUND OF THE INVENTION

1. Field of the Invention

The present invention relates to a nitride semiconductor device and a power conversion apparatus including the same, and more particularly to improvement in a nitride semiconductor device suitable for high-power application requiring operation at high voltage and a power conversion apparatus including the same.

2. Description of the Background Art

Semiconductor elements formed with nitride semiconductor material are expected to be useful as power devices capable of acting at high voltage and high current, because of characteristics inherent to the material. Among these elements, field-effect transistors and diodes that utilize an AlGaN/GaN heterojunction attract attention as devices capable of reducing electric loss in action, because they can realize their low on-resistance by using two-dimensional electron gas (2D electron gas) produced in the heterojunction interface.

In the case that such a field-effect transistor is used in a power switching application, it is required to operate in a so-called normally-off-mode in which current is prevented from flowing in the transistor while voltage is not applied to its gate electrode.

A schematic cross-sectional view of FIG. 13 illustrates a main portion of a conventional nitride semiconductor field-effect transistor capable of acting in the normally-off-mode disclosed in Japanese Patent Laying-Open No. 2007-67240. This transistor includes an AlₓGa₁₋ₓN (0≦x≦1) carrier travel layer 102, an Al_{y}Ga_{1-y}N (0<y<1, x<y) barrier layer 103, an AlₓGa₁₋ₓN (0≦x≦1) threshold control layer 104, an AlₓGa₁₋ₓN (0≦z≦1, x<z) carrier induction layer 105, a source electrode 106, a drain electrode 107, and a gate electrode 108. In an area in which gate electrode 108 is provided, there is formed a recess structure 110 that is dug from an upper surface of carrier induction layer 105 down to a partial depth of threshold control layer 104, and gate electrode 108 is formed on a bottom surface of recess structure 110.

In the field-effect transistor of FIG. 13, a channel (not shown) is produced on a carrier travel layer side of the heterojunction interface between carrier travel layer 102 and barrier layer 103, due to 2D electron gas produced by influence of positive polarization charge at the heterojunction interface. Here, by adjusting the Al composition ratio “y” and thickness of Al_{y}Ga_{1-y}N barrier layer 103 so as to set the concentration of 2D electron gas to be zero in an area under gate electrode 108, it is possible to realize a nitride semiconductor field-effect transistor capable of acting in the normally-off-mode. At this time, the presence of carrier induction layer 105 produces 2D electron gas on the carrier travel layer side of the heterojunction interface between carrier travel layer 102 and barrier layer 103 in areas excluding the area under gate electrode 108, that is, areas under source electrode 106, under between the source and gate electrodes, under between the gate and drain electrodes, and under drain electrode 107, thereby maintaining a low on-resistance of the transistor. As described above, according to the structure shown in FIG. 13, it is possible to provide a nitride semiconductor field-effect transistor capable of acting in the normally-off-mode while suppressing electric loss during on-action.

The inventor of the present invention has carried out detailed examinations by device simulation on the characteristics of the transistor of FIG. 13. Through the examinations, the inventor has found that in the case of increasing voltage applied to drain electrode 107 (drain voltage) under a condition of normally-off-mode in which a voltage is not applied to gate electrode 108 while source electrode 106 is grounded, even a relatively low drain voltage induces an electron flow path from the source to the drain through an interior portion of carrier travel layer 102 downward apart from the heterojunction interface under recess area 110, and thus causes leakage current. It has also been found that in the case of further increasing the drain voltage, a relatively large leakage current can flow between the source and the drain, even in a state that the voltage applied between the source and drain electrodes does not reach the breakdown voltage of the transistor.

As described above, the technique according to FIG. 13 disclosed in Japanese Patent Laying-Open No. 2007-67240 has a problem that in the case of applying a high bias voltage between the source and drain electrodes during off-action, a relatively high leakage current can flow resulting in increase of power consumption of the transistor, and thus it is difficult to provide a nitride semiconductor transistor with low electric loss in off-action for high-power application.

### SUMMARY OF THE INVENTION

In view of the above-described problem in the conventional nitride semiconductor device, an object of the present invention is to provide a nitride semiconductor device that causes less leakage current in the case of applying high bias voltage and causes less electric loss in off-action. Another object of the present invention is to provide a power conversion apparatus including such a nitride semiconductor device, capable of acting with less electric loss and higher efficiency.

A nitride semiconductor device includes: a first, a second, and a third nitride semiconductor layers stacked in this order on a semiconductor underlayer, the third nitride semiconductor layer having a wider band gap as compared with the second nitride semiconductor layer; a recess area that is dug from an upper surface of the third nitride semiconductor layer down to a partial depth of the second nitride semiconductor layer; a first electrode and a second electrode respectively formed on one side and the other side of the recess area so as to be in contact with one of the third nitride semiconductor layer and the second nitride semiconductor layer; a dielectric film formed on the third nitride semiconductor layer and an inner surface of the recess area; and a control electrode formed on the dielectric film in the recess area.

It is preferable that the recess area is dug down to 3 nm or more into the second nitride semiconductor layer from a lower surface of the third nitride semiconductor layer. It is preferable that the control electrode extends over the dielectric film formed on an upper surface of the third nitride semiconductor layer. It is preferable that a lower end of the control electrode is positioned lower than a lower surface of the third nitride semiconductor layer. It is preferable that a portion of the dielectric film formed in contact with a upper surface of the third nitride semiconductor layer and a portion of the dielectric film formed in contact with the inner surface of the recess area are of dielectric materials of kinds different from each other. It is preferable that a distance between an upper surface of the first nitride semiconductor layer and a bottom surface of the recess area is equal to or smaller than 500 nm.

It is preferable that the second nitride semiconductor layer is made of GaN. The first nitride semiconductor layer may include a nitride semiconductor layer that is doped with an impurity to become a p-type or an i-type. It is preferable that the second nitride semiconductor layer has a thickness equal to or greater than 20 nm. The first nitride semiconductor layer may include a nitride semiconductor layer having a narrower band gap as compared with a top surface layer of the semiconductor underlayer and the second nitride semiconductor layer. This first nitride semiconductor layer preferably has a thickness equal to or smaller than 200 nm. The first nitride semiconductor layer may be made of InₓGa₁₋ₓN (0<x≦1). The first nitride semiconductor layer may includes a nitride semiconductor layer having a wider band gap as compared with the second nitride semiconductor layer. This first nitride semiconductor layer preferably has a thickness equal to or greater than 100 nm. This first nitride semiconductor layer may be made of Al_{y}Ga_{1-y}N (0<y≦1). It is preferable that a top surface layer of the semiconductor underlayer is made of GaN, and the first nitride semiconductor layer is made of Al_{y}Ga_{1-y}N (0.03≦y≦0.15).

The first electrode and the control electrode may electrically be connected with each other. It is preferable that the first electrode is in ohmic contact with the second nitride semiconductor layer. The first electrode and the control electrode may be made of the same material.

It is possible to obtain an excellent power conversion apparatus by incorporating therein the nitride semiconductor device according to the present invention as described above.

The foregoing and other objects, features, aspects and advantages of the present invention will become more apparent from the following detailed description of the present invention when taken in conjunction with the accompanying drawings.

### BRIEF DESCRIPTION OF THE DRAWING

FIG. 1 is a schematic cross-sectional view illustrating a nitride semiconductor device of a first embodiment according to the present invention;

FIG. 2 is a graph showing a comparison between characteristics of the field-effect transistor of FIG. 1 and a field-effect transistor of a comparative example;

FIG. 3 is a schematic cross-sectional view illustrating a modified example of the nitride semiconductor device of FIG. 1;

FIG. 4 is a schematic cross-sectional view illustrating a modified example of the nitride semiconductor device of FIG. 3;

FIG. 5 is a schematic cross-sectional view illustrating a modified example of the nitride semiconductor device of FIG. 4;

FIG. 6 is a schematic cross-sectional view illustrating a nitride semiconductor device of a second embodiment according to the present invention;

FIG. 7 is a schematic cross-sectional view illustrating a modified example of the nitride semiconductor device of FIG. 6;

FIG. 8 is a schematic cross-sectional view illustrating a nitride semiconductor device of a third embodiment according to the present invention;

FIG. 9 is a schematic cross-sectional view illustrating a nitride semiconductor device of a fourth embodiment according to the present invention;

FIG. 10 is a schematic cross-sectional view illustrating a modified example of the nitride semiconductor device of FIG. 9;

FIG. 11 is a circuit diagram illustrating a main portion of a power conversion apparatus of a fifth embodiment according to the present invention;

FIG. 12 is a schematic cross-sectional view illustrating a modified example of the nitride semiconductor device of FIG. 4; and

FIG. 13 is a schematic cross-sectional view illustrating a field-effect transistor according to the conventional art.

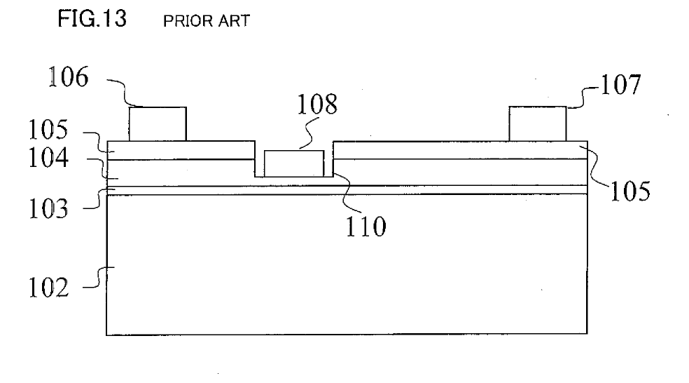

### DESCRIPTION OF THE PREFERRED EMBODIMENTS

### First Embodiment

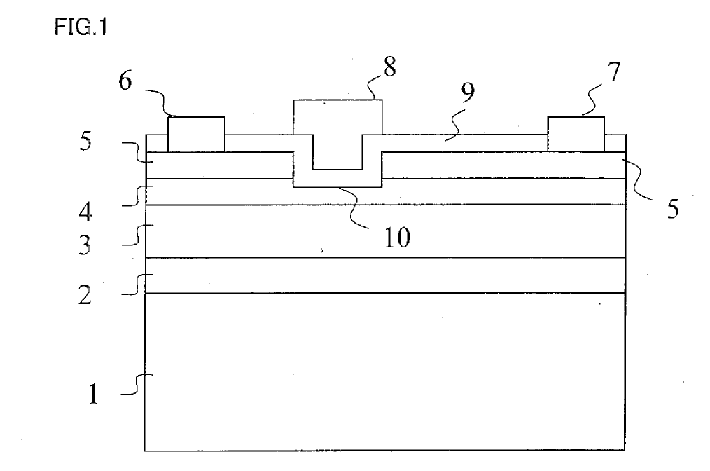

FIG. 1 shows a schematic cross-sectional view illustrating a nitride semiconductor device of a first embodiment according to the present invention. It should be noted that, in the drawings of the present application, the like reference numerals represent the like components or corresponding components. Further, in the drawings of the present application, dimensional relation between length, width, thickness, and such does not represent actual dimensional relation and is arbitrarily modified for the sake of clarity and simplicity of the drawings.

The field-effect transistor shown in FIG. 1 includes a substrate 1, a buffer layer 2, a first nitride semiconductor layer 3, a second nitride semiconductor layer 4 as a carrier travel layer, a third nitride semiconductor layer 5 as a barrier layer having a wide band gap compared to second nitride semiconductor layer 4, a source electrode 6, a drain electrode 7, a gate electrode 8, a dielectric film 9, and a recess structure 10.

Substrate 1 is made of Si. Buffer layer 2 is a nitride semiconductor multilayer in which a thick undoped GaN is formed on a thin undoped AlN layer. First nitride semiconductor layer 3 is a p-type GaN layer of 100 nm thickness doped with Mg as an impurity at a concentration of 1×10¹⁹ cm⁻³. Second nitride semiconductor layer 4 is an undoped GaN layer of 100 nm thickness. Third nitride semiconductor layer 5 is a nitride semiconductor multilayer including undoped GaN/Al_{0.3}Ga_{0.7}N/AlN with thickness of 1 nm/26 nm/3 nm in this order from the top. Source electrode 6 and drain electrode 7 are made of Ti/Al, gate electrode 8 is made of Ni/Au, and dielectric film 9 is made of SiO₂ with thickness of 20 nm.

A channel (not shown) is produced with a two-dimensional electron gas (2D electron gas) on a second nitride semiconductor layer side of a heterojunction interface between second nitride semiconductor layer 4 and third nitride semiconductor layer 5, due to influence of positive polarization charge at the heterojunction interface. Source electrode 6 and drain electrode 7 are formed in contact with third nitride semiconductor layer 5. Source electrode 6 and drain electrode 7 are in ohmic contact with the channel by a tunnel current mechanism through third nitride semiconductor layer 5. Recess structure 10 is formed by being dug from an upper surface of third nitride semiconductor layer 5 down to a partial depth of second nitride semiconductor layer 4. Dielectric film 9 is formed on the upper surface of third nitride semiconductor layer 5 excluding areas where the source and drain electrodes are formed and on an inner surface of recess structure 10. Gate electrode 8 is formed on dielectric film 9 on the inner surface of recess structure 10. Gate electrode 8 servers as a control electrode, which controls electron concentration at interfaces between the dielectric film and the nitride semiconductor layers positioned in downward and lateral directions of the gate electrode, depending on bias voltage applied to gate electrode 8.

Recess structure 10 dug down to the partial depth of second nitride semiconductor layer 4 is required to be provided such that 2D electron gas between the source and the gate and 2D electron gas between the gate and the drain are sufficiently separated when gate voltage is not applied, so as to suppress source-drain current in off-action in which a source-drain voltage is applied without application of the gate voltage. Accordingly, it is desirable that the depth of recess area 10 is equal to or greater than the bottom level of the channel due to the 2D electron gas. More specifically, it is desirable that recess area 10 is dug down to a depth of 3 nm or more from the heterojunction interface between second nitride semiconductor layer 4 and third nitride semiconductor layer 5. In this embodiment, recess structure 10 is dug down to a depth of 10 nm from the heterojunction interface.

Regarding the depth of recess area 10, it is necessary to consider, in addition to the separation of the 2D electron gases, suppressing an occurrence of high leakage current that flows through an interior portion of second nitride semiconductor layer 4 when a high bias voltage is applied between the electrodes in off-action. In this embodiment, the thickness of second nitride semiconductor layer 4 is 100 nm, and therefore a distance between an upper surface of first nitride semiconductor layer 3 and a bottom surface of recess area 10 is 90 nm. In this case, the leakage current hardly flows between the source and the drain in off-action. However, if second nitride semiconductor layer 4 is made too thick without changing the depth of recess area 10, the leakage current can flow through an interior portion of second nitride semiconductor layer 4. Accordingly, it is required to adjust the depth of recess area 10, depending on the thickness of second nitride semiconductor layer 4. In order to suppress the leakage current it is desirable to set the depth of recess area 10 depending on the thickness of second nitride semiconductor layer 4 such that the distance between the upper surface of first nitride semiconductor layer 3 and the bottom surface of recess area 10 is equal to or smaller than 500 nm.

While first nitride semiconductor layer 3 of p-type GaN is doped with Mg as the p-type impurity at a concentration of 1×10¹⁹ cm⁻³, a concentration of holes in the p-type GaN is 1×10¹⁷ cm⁻³, because the activation rate of Mg in GaN is low. The p-type impurity is not limited to Mg and can be any impurity such as Zn, C, and Fe, as long as the impurity can make the nitride semiconductor either p-type or i-type. Since first nitride semiconductor layer 3 serves as a high-resistivity layer against electron flow, it is possible to block an electron flow path that tends to be formed in a region downward apart from the heterojunction interface between second nitride semiconductor layer 4 as the carrier travel layer and third nitride semiconductor layer 5 as the barrier layer when a high bias voltage is applied between the source and drain electrodes in off-action. Thus, it is possible to suppress the leakage current that flows between the source and drain electrodes.

When a nitride semiconductor layer doped with an impurity is used as first nitride semiconductor layer 3, there can be a case in which at the time of forming semiconductor layers sequentially on substrate 1, the impurity diffuses from first nitride semiconductor layer 3 to second nitride semiconductor layer 4 and decreases the concentration and mobility of the 2D electron gas produced at the heterojunction interface between second nitride semiconductor layer 4 and third nitride semiconductor layer 5. Further, if the distance between first nitride semiconductor layer 3 and third nitride semiconductor layer 5 becomes smaller in the case of first nitride semiconductor layer 3 being p-type, the concentration of the 2D electron gas produced at the heterojunction interface between second nitride semiconductor layer 4 and third nitride semiconductor layer 5 decreases due to influence of p-type layer 3. In these cases, the on-resistance increases resulting in increase of electric loss in the nitride semiconductor device as a transistor for high-power application. In order to avoid this problem, it is desirable to set the distance between first nitride semiconductor layer 3 and third nitride semiconductor layer 5 greater than a certain level, that is, to make second nitride semiconductor layer 4 thicker than a certain level. Specifically, it is desirable that the thickness of second nitride semiconductor layer 4 is equal to or greater than 20 nm.

Here, explanation is given for a function of the field-effect transistor shown in FIG. 1. By application of a positive voltage to gate electrode 8, electrons are accumulated in the nitride semiconductor layers that are in contact with the bottom and sides of dielectric film 9 that is in contact with the bottom and sides of gate electrode 8. With these accumulated electrons, the 2D electron gas produced between the source and the gate is connected with the 2D electron gas produced between the gate and the drain. Thus, application of a voltage between the source and drain electrodes causes a current between the source and the drain at a low on-resistance, and can realize on-action with low electric loss.

On the other hand, when gate electrode 8 is supplied with no voltage or 0 V, the 2D electron gas between the source and the gate is separated from the 2D electron gas between the gate and the drain by recess structure 10, thereby realizing normally-off-action in which no current flows through the channel even if a voltage is applied between the source and drain electrodes in off-action. In particular, since first nitride semiconductor layer 3 highly resistive to electron flow is present below recess area 10, even if the voltage applied between the source and drain electrodes is considerably high, the leakage current that flows through a portion downward apart from recess area 10 is suppressed to a large extent, thereby realizing off-action with low electric loss.

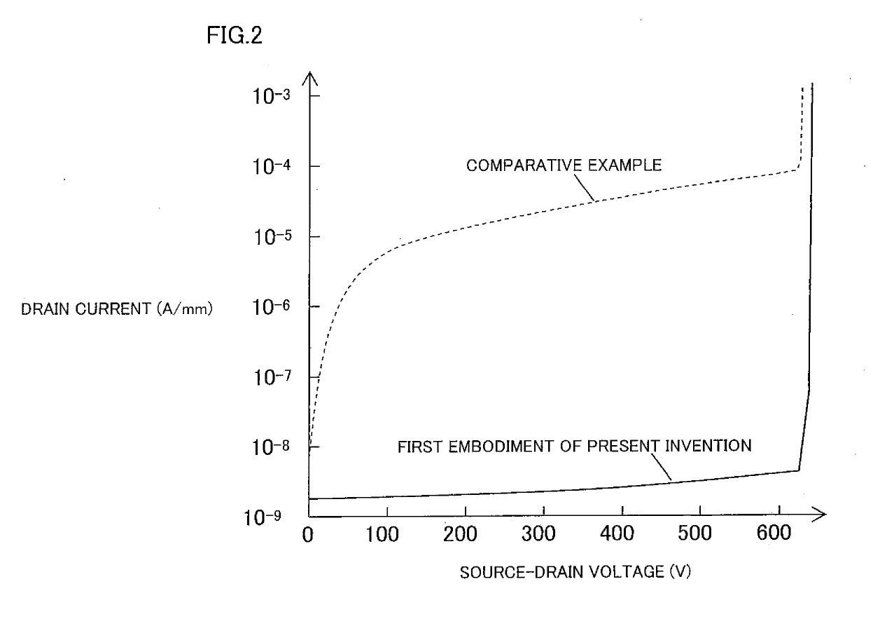

A graph of FIG. 2 shows a comparison between characteristics of the field-effect transistor of the first embodiment as described above and a field-effect transistor of a comparative example. The field-effect transistor of the comparative example is different from the first embodiment only in that an undoped GaN layer is used as first nitride semiconductor layer 3 instead of the p-type GaN layer. A drain current flowing at the time when a voltage was applied between the source and drain electrodes while the gate voltage was 0 V, i.e., a leakage current flowing between the source and the drain in off-action in the field-effect transistor of the first embodiment was compared with that in the field-effect transistor of the comparative example. Here, the source and gate electrodes were connected to the ground potential, and the drain voltage was swept from 0 V to a highly biased level.

As can be seen in FIG. 2, in the field-effect transistor of the comparative example, the drain current shows a sudden increase followed by a gradual increase when the drain voltage rises from 0 V up to 100 V, and then again shows a drastic rise due to breakdown of the device with the drain voltage exceeding 600 V. In the case of the field-effect transistor of the first embodiment, on the other hand, the drain current increases gradually with the drain voltage from 0 V up to near 600 V, and shows a drastic rise due to breakdown of the device with the drain voltage exceeding 600 V. In other words, the transistor of the first embodiment does not show a sudden increase of the current at a drain voltage considerably lower than the breakdown voltage, unlike the comparative example.

As described above, in the nitride semiconductor device of FIG. 1 according to this embodiment, with nitride semiconductor layer 3 being highly resistive to electron flow and provided under carrier travel layer 4, it is possible to suppress electron flow through a portion downward apart from the heterojunction interface between barrier layer 5 and carrier travel layer 4. Accordingly, it is possible to suppress the leakage current that flows between the source and drain electrodes even when a higher bias voltage is applied as compared with the case of the nitride semiconductor device of the conventional technique, thereby suppressing electric loss in off-action.

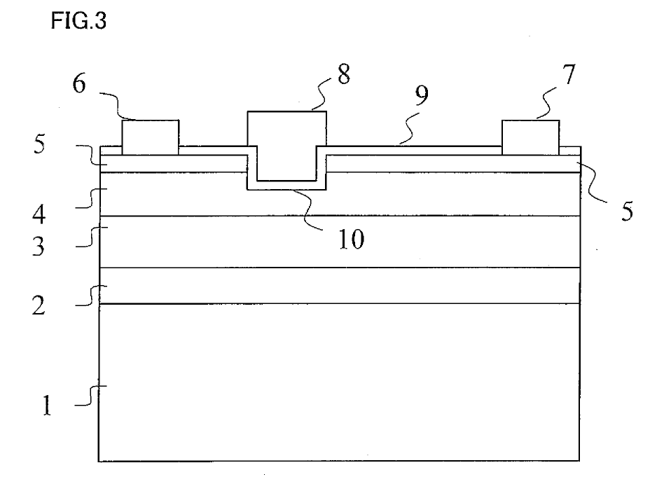

A schematic cross-sectional view of FIG. 3 illustrates a nitride semiconductor device of a modified example 1 of the first embodiment. In the nitride semiconductor device of FIG. 1, the depth of recess area 10 and the thickness of dielectric film 9 are set so that the lower end of gate electrode 8 is positioned higher than the interface between second nitride semiconductor layer 4 as the carrier travel layer and third nitride semiconductor layer 5 as the barrier layer. On the other hand, the nitride semiconductor device of this modified example 1 shown in FIG. 3 is different from the device of FIG. 1 only in that the depth of recess area 10 and the thickness of dielectric film 9 are set so that the lower end of gate electrode 8 is positioned lower than the interface between second nitride semiconductor layer 4 and third nitride semiconductor layer 5.

More specifically, in the device of modified example 1, the thickness of dielectric film 9 is set to 20 nm similarly to the case of FIG. 1, and recess area 10 is dug down to a depth of 30 nm from the heterojunction interface between second nitride semiconductor layer 4 and third nitride semiconductor layer 5. With such a structure of modified example 1, when gate electrode 8 is supplied with a positive voltage more electrons can be accumulated at the interface between dielectric film 9 and second nitride semiconductor layer 4 in a lateral direction from recess area 10. As a result, the source-drain current can flow with a lower on-resistance in on-action in which the voltage is applied between the source and drain electrodes, while the leakage current in off-action can be reduced, thereby allowing on-action with lower electric loss.

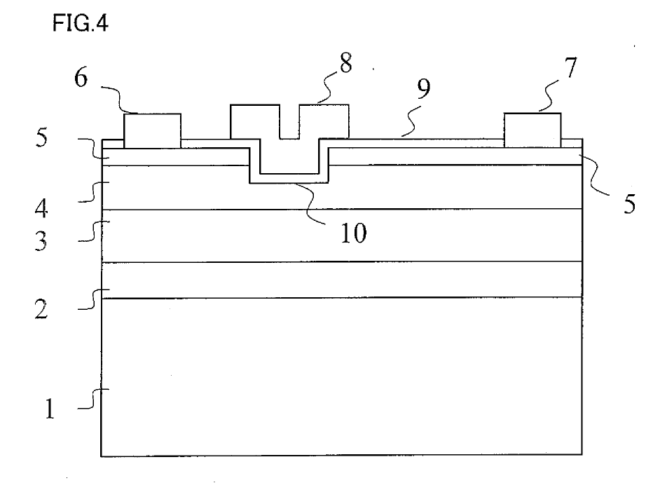

A schematic cross-sectional view of FIG. 4 illustrates a nitride semiconductor device of a modified example 2 of the first embodiment. Modified example 2 of FIG. 4 is different from modified example 1 of FIG. 3 only in that gate electrode 8 on dielectric film 9 extends over recess area 10. More specifically, in this modified example 2, gate electrode 8 extends over recess area 10 by 0.5 μm toward each of the source and drain electrodes.

With such a structure of modified example 2, when gate electrode 8 is supplied with a positive voltage, more electrons can be accumulated at the interface between dielectric film 9 and second nitride semiconductor layer 4 in the lateral direction from recess area 10, and the concentration of 2D electron gas produced at the heterojunction interface between second nitride semiconductor layer 4 and third nitride semiconductor layer 5 can be higher in an area under gate electrode 8. As a result, the source-drain current can flow with further lower on-resistance in on-action in which the voltage is applied between the source and drain electrodes, while the leakage current in off-action can be reduced, thereby allowing on-action with lower electric loss.

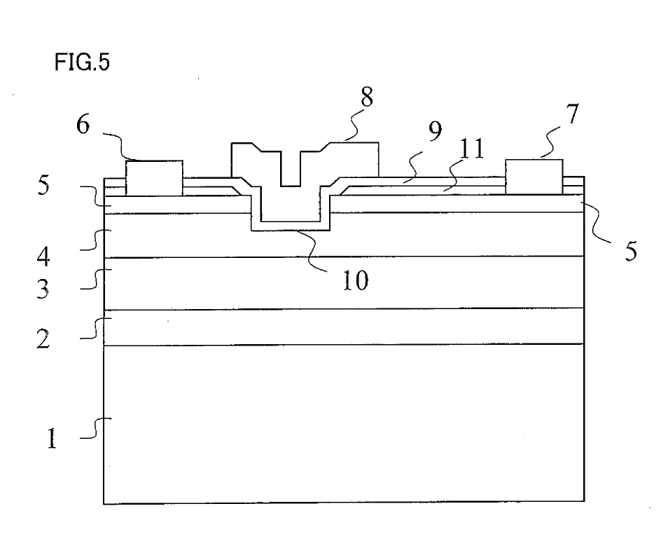

A schematic cross-sectional view of FIG. 5 illustrates a nitride semiconductor device of a modified example 3 of the first embodiment. This modified example 3 of FIG. 5 is different from modified example 2 of FIG. 4 in that a dielectric film 11 of a different type is inserted under dielectric film 9 in areas other than recess area 10. More specifically, in modified example 3, dielectric film 9 is made of SiO₂, and dielectric film 11 is made of SiN. Further, gate electrode 8 in FIG. 5 is formed in an asymmetric structure extending over recess area 10 by 0.5 μm toward the source electrode and by 1.5 μm toward the drain electrode.

That is, in modified example 3, high withstand voltage SiO₂ dielectric film 9 is provided for recess area 10 where higher field intensity is generated within the dielectric film in on-action and for a drain-side end portion of gate electrode 8 where higher field intensity is generated within the dielectric film in off-action. On the other hand, SiN dielectric film 11 for reducing interface state density is provided on third nitride semiconductor layer 5 in an area where higher field intensity is generated within the semiconductor layer on the drain side of gate electrode 8 in off-action. In this manner, it is possible to satisfy the requirements of high withstand voltage and low interface state density at the same time by using two types of dielectric films, and the nitride semiconductor device with low electric loss in off-action can be obtained without causing deterioration in its characteristics relating to the withstand voltage and the interface state density.

### Second Embodiment

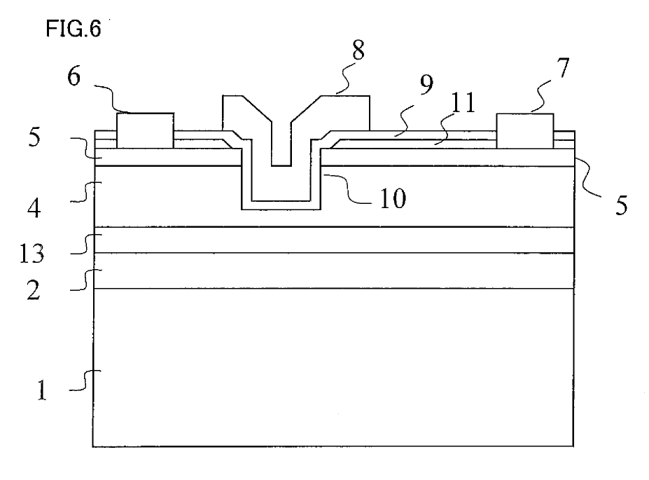

FIG. 6 is a schematic cross-sectional view illustrating a nitride semiconductor device of a second embodiment according to the present invention. The field-effect transistor of FIG. 6 is different from the transistor of FIG. 5 in that first nitride semiconductor layer 3 of p-type GaN is replaced with a first nitride semiconductor layer 13 of p-type InGaN. That is, first nitride semiconductor layer 13 has a narrower band gap as compared with buffer layer 2.

More specifically, first nitride semiconductor layer 13 is made of p-type In_{0.1}Ga_{0.9}N doped with Mg at a concentration of 1×10¹⁹ cm⁻³, and has a thickness of 50 nm. Further, second nitride semiconductor layer 4 made of undoped GaN is 200 nm thick. First nitride semiconductor layer 13, second nitride semiconductor layer 4, and third nitride semiconductor layer 5 are lattice-matched with a GaN layer as a top layer included in buffer layer 2. Recess area 10 is dug down to a depth of 150 nm from the heterojunction interface between second nitride semiconductor layer 4 and third nitride semiconductor layer 5.

While first nitride semiconductor layer 13 is doped with Mg at a concentration of 1×10¹⁹ cm⁻³, the activation rate of Mg in InGaN is higher as compared to that in GaN, and then the concentration of holes in p-type In_{0.1}Ga_{0.9}N layer becomes 13 1×10¹⁸ cm⁻³. In order to reduce influence of p-type layer 13 having the higher hole concentration on the concentration of 2D electron gas produced at the heterojunction interface between second nitride semiconductor layer 4 and third nitride semiconductor layer, the thickness of second nitride semiconductor layer 4 is set to be 200 nm in this embodiment as described above.

It should be noted that first nitride semiconductor layer 13 of InGaN is not necessarily required to be doped with an impurity for making the layer p-type or i-type. First nitride semiconductor layer 13 is not limited to InGaN, and as long as a material having a lattice constant and a band gap respectively greater and narrower than those of the top layer material included in buffer layer 2 is provided as a strained pseudomorphic layer on the buffer layer, a negative polarization charge can be produced at the heterojunction interface between buffer layer 2 and first nitride semiconductor layer 13, and the charge and a conduction band discontinuity at the heterojunction interface can form a barrier against electrons. As a result, when a high bias voltage is applied between the source and drain electrodes in off-action, it is possible to block an electron flow path through a portion of buffer layer 2 downward apart from the heterojunction interface between third nitride semiconductor layer 5 as the barrier layer and second nitride semiconductor layer 4 as the carrier travel layer, thereby suppressing the leakage current that flows between the source and drain electrodes.

At this time, a leakage current is liable to flow through first nitride semiconductor layer 13 when the band gap of the first nitride semiconductor layer 13 is narrower than that of second nitride semiconductor layer 4. Therefore, it is desirable that the thickness of first nitride semiconductor layer 13 is equal to or smaller than 200 nm, and is doped with an impurity so as to be p-type or i-type. Although InGaN is used as first nitride semiconductor layer 13 in this embodiment, any material can be used as long as first nitride semiconductor layer 13 is a nitride semiconductor layer having a band gap narrower than that of the top layer material of the buffer layer, as described above. However, it is desirable to use InₓGa₁₋ₓN (0<x≦1) which is a ternary mixed crystal, considering facilitation of control of the mixed-crystal composition.

Here, explanation is given for a function of the field-effect transistor of FIG. 6. By application of a positive voltage on gate electrode 8, electrons are accumulated within the nitride semiconductor layers that are positioned in downward and lateral directions of dielectric films 9 and 11 positioned in downward and lateral directions of gate electrode 8. These accumulated electrons connect the 2D electron gas produced between the source and the gate to the 2D electron gas produced between the gate and the drain. Thus, application of a voltage between the source and drain electrodes causes a current flowing between the source and the drain with a low on-resistance, and can realize on-action with low electric loss.

On the other hand, when gate electrode 8 is supplied with no voltage or 0 V, the 2D electron gas between the source and the gate is separated form the 2D electron gas between the gate and the drain by recess structure 10, and thus realizing normally-off-action in which no current flows through the channel even if a voltage is applied between the source and drain electrodes in off-action. In particular, since first nitride semiconductor layer 13 forming the barrier against electrons is present below recess area 10, the leakage current that flows through buffer layer 2 downward apart from recess area 10 is suppressed to a large extent even if a voltage applied between the source and drain electrodes is considerably high, thereby realizing on-action with low electric loss.

As described above, in the nitride semiconductor device according to the second embodiment, by providing nitride semiconductor layer 13 that forms the barrier against electrons under carrier travel layer 4, it is possible to suppress the current flow through the portion downward apart from the heterojunction interface between barrier layer 5 and carrier travel layer 4. Similarly to the case of the first embodiment as described before, therefore, it is also possible in the second embodiment to reduce the leakage current that flows between the source and drain electrodes even when a higher bias voltage is applied as compared with the case of the nitride semiconductor device of the conventional technique, thereby realizing the nitride semi conductor device with low electric loss in off-action.

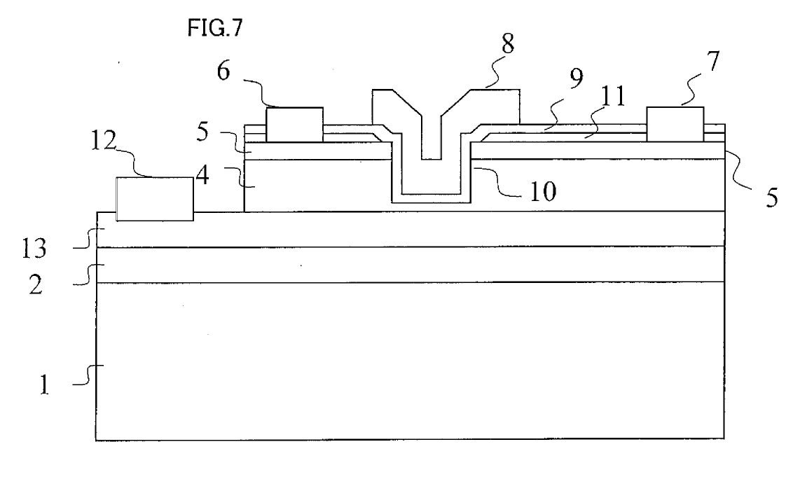

A schematic cross-sectional view of FIG. 7 shows a modified example of the nitride semiconductor device of FIG. 6 (hereinafter referred to as modified example 4). The field-effect transistor of FIG. 7 is different from that of FIG. 6 in that an electrode 12 for a RESURF (reduced surface field) layer is additionally formed on first nitride semiconductor layer 13 of p-type InGaN. Details regarding effects of a RESURF structure are described in U.S. Pat. No. 6,100,549.

In FIG. 7) electrode 12 is made of Ni/Au. The field-effect transistor structure as shown in FIG. 7 includes a RESURF structure that can decrease the field intensity produced at the heterojunction interface between second nitride semiconductor layer 4 and third nitride semiconductor layer 5 in off-action, and therefore it is possible to reduce the leakage current in off-action, and at the same time, it is possible to either improve the withstand voltage or reduce the on-resistance.

### Third Embodiment

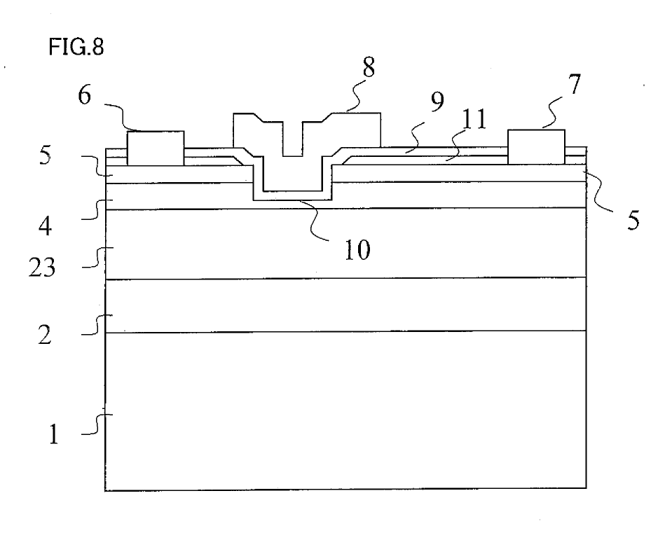

FIG. 8 is a schematic cross-sectional view illustrating a nitride semiconductor device of a third embodiment according to the present invention. The field-effect transistor of FIG. 8 is different from the transistor of FIG. 5 in that first nitride semiconductor layer 3 of p-type GaN is replaced with a first nitride semiconductor layer 23 of AlGaN. That is, first nitride semiconductor layer 23 has a wider band gap as compared with the top layer of buffer layer 2 and second nitride semiconductor layer 4.

More specifically, first nitride semiconductor layer 23 is made of undoped Al_{0.05}Ga_{0.95}N, and has a thickness of 500 nm. Further, second nitride semiconductor layer 4 of undoped GaN is set to be 40 nm thick. Recess area 10 is dug down to a depth of 30 nm from the heterojunction interface between third nitride semiconductor layer 5 and second nitride semiconductor layer 4.

First nitride semiconductor layer 23 is not limited to AlGaN, and as long as a material having a lattice constant and a band gap respectively smaller and wider than those of second nitride semiconductor layer 4 is provided as first nitride semiconductor layer 23, a negative polarization charge can be produced at the heterojunction interface between first nitride semiconductor layer 23 and second nitride semiconductor layer 4, and the charge and a conduction band discontinuity at the heterojunction interface can form a barrier against electrons. As a result, when a high bias voltage is applied between the source and drain electrodes in off-action, it is possible to block an electron flow path through a portion downward apart from the heterojunction interface between barrier layer 5 and carrier travel layer 4, thereby suppressing the leakage current that flows between the source electrode and drain electrodes.

Here, explanation is given for a function of the field-effect transistor shown in FIG. 8. When a positive voltage is applied to gate electrode 8, electrons are accumulated within the nitride semiconductor layers that are positioned in downward and lateral directions of dielectric films 9 and 11 positioned in downward and lateral directions of gate electrode 8. These accumulated electrons connect the 2D electron gas produced between the source and the gate to the 2D electron gas produced between the gate and the drain. Thus, application of a voltage between source and drain causes a current flowing between the source and the drain with a low on-resistance, and can realize on-action with low electric loss.

On the other hand, when gate electrode 8 is supplied with no voltage or 0 V, the 2D electron gas between the source and the gate is separated from the 2D electron gas between the gate and the drain by recess structure 10, and thus realizing normally-off-action in which no current flows through the channel even if a voltage is applied between the source and drain electrodes in off-action. In particular, since first nitride semiconductor layer 23 forming the barrier against electrons is present below recess area 10, the leakage current that flows through a portion downward apart from recess area 10 is suppressed to a large extent even if a considerably high voltage is applied between the source and drain electrodes, thereby realizing off-action with low electric loss.

As described above, in the nitride semiconductor device of the third embodiment, by providing nitride semiconductor layer 23 that forms the barrier against electrons under carrier travel layer 4, it is possible to suppress the electron flow through a portion downward apart from the heterojunction interface between barrier layer 5 and carrier travel layer 4. Similarly to the case of the first embodiment as described above, therefore, it is also possible in the third embodiment to reduce the leakage current that flows between the source and drain electrodes even when a higher bias voltage is applied as compared with the case of the nitride semiconductor device of the conventional technique, thereby realizing a nitride semiconductor device with low electric loss in off-action.

Although AlGaN is used for first nitride semiconductor layer 23 in this embodiment, any material can be used as long as first nitride semiconductor layer 23 is a nitride semiconductor layer having a band gap wider than that of second nitride semiconductor layer 4 as described above. However, it is desirable to use Al_{y}Ga_{1-y}N (0<y≦1) that is a ternary mixed crystal, considering facilitation of control of the mixed-crystal composition.

Here, if first nitride semiconductor layer 23 is thin, electrons can transmit as a tunnel current through first nitride semiconductor layer 23 and then the leakage current can flow through buffer layer 2. Therefore, it is desirable that the thickness of first nitride semiconductor layer 23 is equal to or greater than 100 nm. Further, if the Al composition ratio in first nitride semiconductor layer 23 is high, 2D electron gas can be produced at the heterojunction interface between first nitride semiconductor layer 23 and buffer layer 2, and then an electrons flow path can be formed within buffer layer 2. In order to avoid this problem, it is necessary to appropriately select materials for buffer layer 2 and first nitride semiconductor layer 23. For example, when the top layer included in buffer layer 2 is made of GaN and first nitride semiconductor layer 23 is made of Al_{y}Ga_{1-y}N, it is possible to suppress the production of 2D electron gas if the Al composition ratio “y” of first nitride semiconductor layer 23 is in a range of 0.03≦y≦0.15.

### Fourth Embodiment

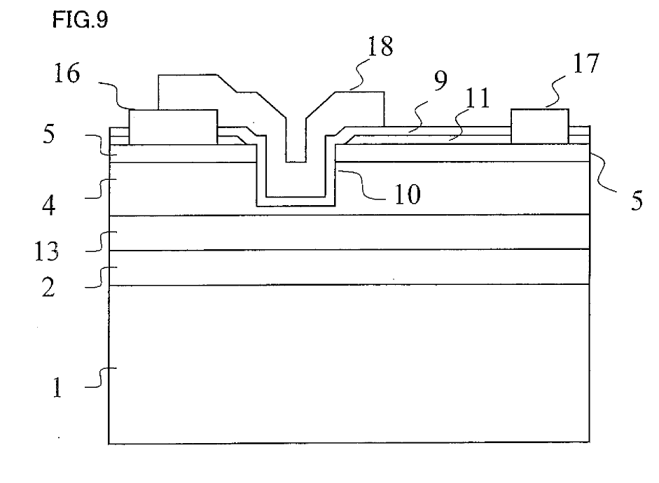

FIG. 9 is a schematic cross-sectional view illustrating a nitride semiconductor device of a fourth embodiment according to the present invention. In the structure of the diode of FIG. 9 in comparison with the structure of the transistor of FIG. 6, an anode electrode 16 corresponds to source electrode 6, and a cathode electrode 17 corresponds to drain electrode 7. The anode and cathode electrodes are both made of Ti/Al. Further, gate electrode 18 is formed on anode electrode 16 and dielectric films 9 and 11, and thus connected electrically to anode electrode 16. This gate electrode 18 is made of Ni/Au.

Although gate electrode 18 in FIG. 9 electrically connects to anode electrode 16 by covering on top of anode electrode 16, gate electrode 18 may electrically be connected to anode electrode 16 by a configuration in which anode electrode 16 covers on top of gate electrode 18, or in which the gate and anode electrodes are not in direct contact with each other and are electrically connected via a wiring electrode.

Anode electrode 16 and cathode electrode 17 are formed in contact with third nitride semiconductor layer 5. Then, each of anode electrode 16 and cathode electrode 17 is in ohmic contact with a channel (not shown) due to 2D electron gas produced at an upper surface of second nitride semiconductor layer 4, by a tunnel current mechanism through third nitride semiconductor layer 5. Gate electrode 18 serves as a control electrode that controls concentration of electrons, depending on bias voltage applied on gate electrode 18, at interfaces between dielectric films 9 and 11 and the nitride semiconductor layers positioned in downward and lateral directions of the gate electrode.

Here, explanation is given for a function of the diode shown in FIG. 9. When voltages at anode electrode 16 and gate electrode 18 are 0 V, the 2D electron gas produced between the anode and the gate is separated from the 2D electron gas produced between the gate and the cathode by recess structure 10.

When a forward bias voltage is applied between anode electrode 16 and cathode electrode 17, electrons are accumulated within the nitride semiconductor layer that is positioned in downward and lateral directions of dielectric films 9 and 11 positioned in downward and lateral directions of gate electrode 18 connected electrically to anode electrode 16. These accumulated electrons connect the 2D electron gas produced between the anode and the gate to the 2D electron gas produced between the gate and the cathode, and thus a current flows from anode electrode 16 to cathode electrode 17.

On the other hand, when a reverse bias voltage is applied between anode electrode 16 and cathode electrode 17, current is blocked due to depletion of electrons in the vicinity of gate electrode 18 electrically connected to anode electrode 16 and of the 2D electron gas between the gate and the cathode.

As seen above, in the diode according to the fourth embodiment, rectification can be realized by controlling the electron concentration in the vicinity of gate electrode 18 via dielectric films 9 and 11. In particular, since first nitride semiconductor layer 13 forming the barrier against electrons is present below recess area 10, the leakage current that flows through buffer layer 2 downward apart from recess area 10 is suppressed to a large extent, thereby allowing on-action with low electric loss.

As described above, in the nitride semiconductor device according to the fourth embodiment, by providing nitride semiconductor layer 13 that forms the barrier against electrons under carrier travel layer 4, it is possible to suppress the current flow through a portion downward apart from the heterojunction interface between barrier layer 5 and carrier travel layer 4. Therefore, it is possible to reduce the leakage current that flows between the anode and cathode electrodes even when a high reverse bias voltage is applied, thereby reducing electric loss in off-action.

Further, in this embodiment, since anode electrode 16 is in ohmic contact with the channel, current starts to flow at a lower voltage as compared to the case of a so-called Schottky diode using an anode electrode that forms a Schottky junction instead of recess structure 10, and the turn-on voltage when the forward bias is applied can be made closer to 0 V. As a result, it is possible to reduce the power loss in on-action.

Here, in this embodiment, since gate electrode 18 is provided and electrically connected to anode electrode 16, the field intensity is maximized at a cathode-side end of gate electrode 18 when the reverse bias voltage is applied. On the other hand, in the case of the so-called Schottky diode that uses the anode electrode forming the Schottky junction instead of recess structure 10, the field intensity is maximized at a cathode-side end of the anode electrode. In this embodiment, dielectric films 9 and 11 are present between the semiconductor layers and the side end of the electrode where the field intensity is maximized. Therefore, in this embodiment compared to a typical Schottky diode that does not include a dielectric film, reverse leakage current caused at the side end of the electrode where the field intensity is high can be reduced to a large extent, and it is possible to improve the withstand voltage in off-action.

Regarding FIG. 9, the diode in which anode electrode 16 and gate electrode 18 are electrically connected is described based on the structure of the field-effect transistor of FIG. 6. However, it goes without saying that p-type GaN layer 3 or AlGaN layer 23 in the first or third embodiment can also be used instead of first nitride semiconductor layer 13 in FIG. 9.

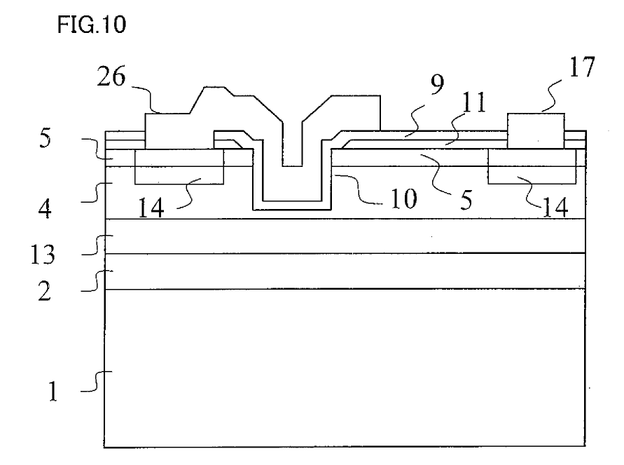

A schematic cross-sectional view in FIG. 10 shows a modified example of the nitride semiconductor device of FIG. 9 (hereinafter referred to as modified example 5). The diode of FIG. 10 is different from that of FIG. 9 in that the gate electrode and the anode electrode constitute a composite anode electrode 26 that is made of the same material. This composite anode electrode 26 is made of Ti/Al as in the case of cathode electrode 17. In each of areas in which composite anode electrode 26 and cathode electrode 17 are in contact with third nitride semiconductor layer 5, a contact region 14 is formed by doping third nitride semiconductor layer 5 and second nitride semiconductor layer 4 with an n-type impurity such as Si at a high concentration using ion implantation or the like. Composite anode electrode 26 and cathode electrode 17 are in ohmic contact with the channel via contact region 14.

In modified example 5 shown in FIG. 10, since composite anode electrode 26 and cathode electrode 17 are made of the same material, it is possible to simplify a process of fabricating the diode and then to provide at reduced cost a nitride semiconductor device having the same characteristics as the diode of FIG. 9.

### Fifth Embodiment

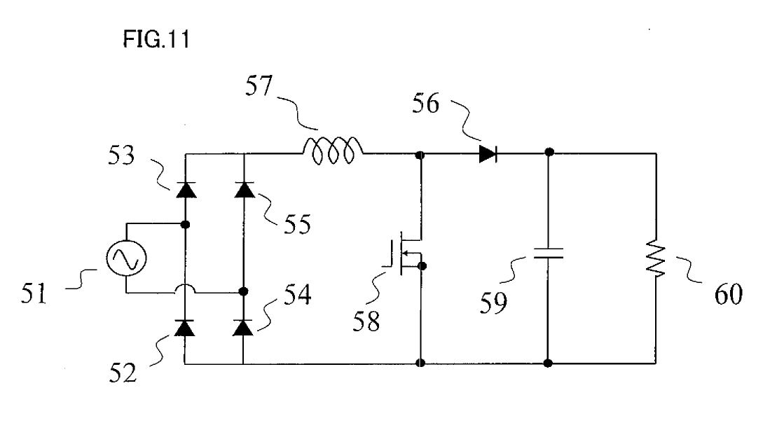

FIG. 11 is a circuit diagram illustrating a main portion of a power conversion apparatus of a fifth embodiment according to the present invention. The power factor improvement circuit of FIG. 11 includes an alternating-current source 51, diodes 52 to 56, an inductor 57, a field-effect transistor 58, a capacitor 59, and a load resistance 60. The nitride semiconductor device according to the fourth embodiment shown in FIG. 9 is used for diodes 52 to 56, and the nitride semiconductor device according to modified example 4 of the second embodiment shown in FIG. 7 is used for field-effect transistor 58.

By applying the nitride semiconductor device of the present invention to the diodes and the field-effect transistor used in the power factor improvement circuit as a power conversion apparatus, electric loss within the circuit can be reduced and thus it becomes possible to improve efficiency of the power conversion apparatus and to provide the power conversion apparatus capable of acting at high efficiency with low electric loss.

While the present invention has been explained in detail based on its embodiments, the present invention is not limited to the above embodiments and can be modified in various manners without departing from the spirit of the present invention.

For example, while Si is used for the substrate in the above embodiments, it is also possible to use a substrate of a different type such as GaN, SiC, AlN, GaAs, or ZnO.

Further, while the nitride semiconductor multilayer in which the thick undoped GaN layer is formed on the thin undoped AlN layer is used as the buffer layer in the above embodiments, it is also possible to use a different-type buffer layer formed of an AlN layer, a GaN layer, an AlGaN layer, an AlN/GaN multilayer, an AlGaN/GaN multilayer, or the like.

Further, while the first, second, and third nitride semiconductor layers are stacked in this order on the top of the buffer layer serving as a semiconductor underlayer in the above embodiments, it is also possible to stack the first, second, and third nitride semiconductor layers in this order directly on the substrate without providing the buffer layer. In this case, the substrate serves as a semiconductor underlayer.

Further, while the undoped GaN layer is used as second nitride semiconductor layer 4 in the above embodiments, second nitride semiconductor layer 4 can be a doped nitride semiconductor layer such as an n-type GaN layer or a p-type GaN layer, or can be a doped or undoped nitride semiconductor layer of a material such as AlGaN, InGaN, AlInN, AlGaInN, or the like other than GaN. However, there is a problem that the mobility of electrons in carrier travel layer 4 tends to decreases due to scattering in a mixed crystal of a ternary or more system, whereby causing increase of electric loss in the nitride semiconductor device acting as a high-power device. Therefore, it is preferable that second nitride semiconductor layer 4 is made of GaN.

Further, while in the above embodiments, the undoped nitride semiconductor multilayer including GaN, Al_{0.3}Ga_{0.7}N, and AlN in this order from the top is used as third nitride semiconductor layer 5, it is also possible to use a different semiconductor layer such as a single nitride semiconductor layer of doped AlGaN, AlIriN or AlGaInN, or undoped AlGaN, an AlGaN multilayer including a plurality of AlGaN layers having different composition ratios of Al and/or different doping concentrations, a nitride semiconductor multilayer of GaN/AlGaN, InGaN/AlGaN or InGaN/AlGaN/AlN, or another semiconductor layer that is single-layered or multi-layered as well as doped or undoped.

Further, while the electrodes made of Ti/Al and Ni/Au are explained in the above embodiments, the electrodes can also be made of different material such as Ti/Au, Pt/Au, Ni/Au, W, WNₓ, or WSiₓ.

Further, while the drain electrode or the cathode electrode is in ohmic contact with the channel of 2D electron gas produced at the heterojunction interface between second nitride semiconductor layer 4 and third nitride semiconductor layer 5 in the above embodiments, the drain electrode or the cathode electrode may be configured to form a Schottky junction. However, in order to reduce the on-resistance and electric electric loss in the nitride semiconductor device, it is desirable that the drain electrode or the cathode electrode is in ohmic contact with the channel.

In the above embodiments, the configurations for bringing the electrode into ohmic contact with the channel have been described based on the case in which the ohmic contact is realized by the tunnel current mechanism through third nitride semiconductor layer 5, and the case in which the ohmic contact is realized by forming the electrode on contact region 14 that is formed by locally doping third nitride semiconductor layer 5 and second nitride semiconductor layer 4 with the n-type impurity such as Si at a high concentration using ion implantation or the like. However, it is also possible to realize the ohmic contact with any of various different methods. For example, the ohmic contact may be realized through the side of second nitride semiconductor layer 4, may be realized by forming the electrode on a highly doped GaN or InGaN contact layer formed by regrowth in an area recessed from the upper surface of third nitride semiconductor layer 5 down to a partial depth of second nitride semiconductor layer 4, may be realized by a tunnel current mechanism through third nitride semiconductor layer 5 by forming the electrode in an area dug down to a partial depth of third nitride semiconductor layer 5, or may be realized by forming the electrode on third nitride semiconductor layer 5 and conducting a heat treatment for alloying without forming a recess into third nitride semiconductor layer 5 and second nitride semiconductor layer 4.

Further, while SiO₂ or SiN is mentioned for material of the dielectric film in the above embodiments, it is also possible to use a different dielectric film such as a layer of Al₂O₃, HfO₂, ZrO₂, TiO₂, TaOₓ, MgO, Ga₂O₃, or MgF₂, or such as a multilayer of SiN/SiO₂ or SiN/SiO₂/SiN.

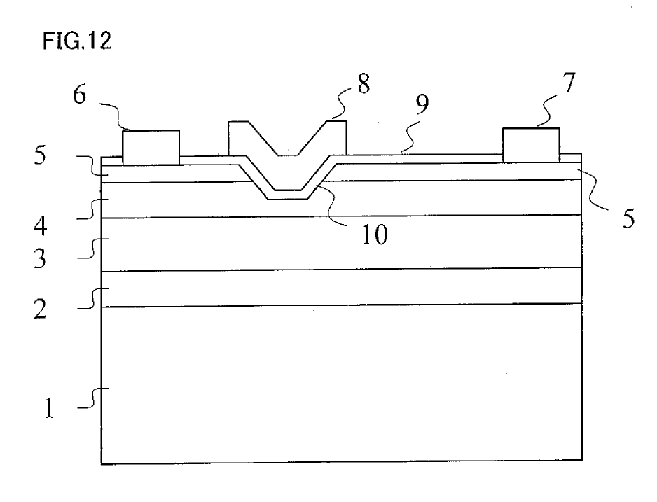

In the present invention, the side surface of recess structure 10 is not required to be vertical to the surface of third nitride semiconductor layer 5. For example, as shown in the example of FIG. 12 that is modified from the example of FIG. 4, the side surface of recess structure 10 may be slanted to the surface of the semiconductor layer.

In the power conversion apparatus of FIG. 11, the nitride semiconductor device according to the present invention is applied to all of the diodes and the field-effect transistor. However, the nitride semiconductor device according to the present invention may be applied to a part of the diodes and the field-effect transistor.

Further, while FIG. 11 shows the example in which the nitride semiconductor devices according to the present invention are applied to the power factor controller, the nitride semiconductor devices according to the present invention can be applied to a different power conversion apparatus such as an inverter or a converter.

As described above, according to the present invention, it is possible to provided the nitride semiconductor device in which the leakage current generated at a high bias voltage is small and the electric loss in off-action is small, and the power conversion apparatus capable of acting at high efficiency with low electric loss by utilizing the nitride semiconductor device.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A nitride semiconductor device comprising:
a first, a second, and a third nitride semiconductor layers stacked in this order on a semiconductor underlayer, said third nitride semiconductor layer having a wider band gap as compared with said second nitride semiconductor layer;
a recess area that is dug from an upper surface of said third nitride semiconductor layer down to a partial depth of said second nitride semiconductor layer;
a first electrode and a second electrode respectively formed on one side and the other side of said recess area so as to be in contact with one of said third nitride semiconductor layer and said second nitride semiconductor layer;
a dielectric film formed on said third nitride semiconductor layer and an inner surface of said recess area; and
a control electrode formed on said dielectric film in said recess area.

2. The nitride semiconductor device according to claim 1, wherein
said recess area is dug down to 3 nm or more into said second nitride semiconductor layer from a lower surface of said third nitride semiconductor layer.

3. The nitride semiconductor device according to claim 1, wherein
said control electrode extends over said dielectric film formed on an upper surface of said third nitride semiconductor layer.

4. The nitride semiconductor device according to claim 1, wherein
a lower end of said control electrode is positioned lower than a lower surface of said third nitride semiconductor layer.

5. The nitride semiconductor device according to claim 1, wherein
a portion of the dielectric film formed in contact with a upper surface of said third nitride semiconductor layer and a portion of the dielectric film formed in contact with the inner surface of said recess area are of dielectric materials of kinds different from each other.

6. The nitride semiconductor device according to claim 1, wherein
a distance between an upper surface of said first nitride semiconductor layer and a bottom surface of said recess area is equal to or smaller than 500 nm.

7. The nitride semiconductor device according to claim 1, wherein said second nitride semiconductor layer is made of GaN.

8. The nitride semiconductor device according to claim 1, wherein
said first nitride semiconductor layer includes a nitride semiconductor layer that is doped with an impurity to become a p-type or an i-type.

9. The nitride semiconductor device according to claim 8, wherein
said second nitride semiconductor layer has a thickness equal to or greater than 20 nm.

10. The nitride semiconductor device according to claim 1, wherein
said first nitride semiconductor layer includes a nitride semiconductor layer having a narrower band gap as compared with said second nitride semiconductor layer and a top surface layer of said semiconductor underlayer.

11. The nitride semiconductor device according to claim 10, wherein
said first nitride semiconductor layer has a thickness equal to or smaller than 200 nm.

12. The nitride semiconductor device according to claim 10, wherein,
said first nitride semiconductor layer is made of InₓGa₁₋ₓN (0<x≦1).

13. The nitride semiconductor device according to claim 1, wherein
said first nitride semiconductor layer includes a nitride semiconductor layer having a wider band gap as compared with said second nitride semiconductor layer.

14. The nitride semiconductor device according to claim 13, wherein
said first nitride semiconductor layer has a thickness equal to or greater than 100 nm.

15. The nitride semiconductor device according to claim 13, wherein
said first nitride semiconductor layer is made of Al_{y}Ga_{1-y}N (0≦y≦1).

16. The nitride semiconductor device according to claim 13, wherein
a top surface layer of said semiconductor underlayer is made of GaN, and said first nitride semiconductor layer is made of Al_{y}Ga_{1-y}N (0.03≦y≦0.15).

17. The nitride semiconductor device according to claim 1, wherein
said first electrode and said control electrode are electrically connected with each other.

18. The nitride semiconductor device according to claim 1, wherein
said first electrode is in ohmic contact with said second nitride semiconductor layer.

19. The nitride semiconductor device according to claim 1, wherein
said first electrode and said control electrode are made of the same material.

20. A power conversion apparatus comprising the nitride semiconductor device of claim 1.
